(19) United States
(12) Patent Application Publication
(10) Pub. No.: US 2026/0255860 A1
(43) Pub. Date: Aug. 27, 2026

(54) DISPLAY DEVICE

(71) Applicant: LG Display Co., Ltd., Seoul (KR)

(72) Inventors: Byung-Gwan HYUN, Paju-si (KR); Won-Rae KIM, Paju-si (KR); Seung-Cheol YOU, Paju-si (KR); Ui-Hyeon JEONG, Paju-si (KR)

(21) Appl. No.: 19/372,395

(22) Filed: Oct. 29, 2025

(30) Foreign Application Priority Data
Feb. 27, 2025 (KR) 10-2025-0025551

(51) Int. Cl. H10K 59/80; H10H 29/37; H10H 29/855; H10K 59/122; H10K 59/40

(52) U.S. Cl. CPC H10K 59/8792; H10H 29/37; H10H 29/855; H10H 29/8552; H10K 59/122; H10K 59/40; H10K 59/879

(57) ABSTRACT

A display device including a substrate having an emission area and a non-emission area, a light-emitting diode disposed on the substrate in the emission area, a touch sensor disposed on the light-emitting diode, an organic insulating layer disposed on the touch sensor, an inorganic buffer layer disposed on the organic insulating layer, and a black matrix disposed on the inorganic buffer layer in the non-emission area, in which the organic insulating layer has a plurality of first uneven patterns on a surface thereof in the non-emission area, and the inorganic buffer layer has a plurality of second uneven patterns on a surface thereof in the non-emission area.

### CROSS REFERENCE TO RELATED APPLICATION

This application claims priority from and the benefit of Korean Patent Application No. 10-2025-0025551, filed on February 27, 2025, which is hereby incorporated by reference for all purposes as if fully set forth herein.

### BACKGROUND

### Field

Embodiments of the invention relate generally to a display device, and more particularly to, a display device capable of minimizing stains caused by a reflection of an external light and realizing beneficial reflection visibility by preventing external light reflection.

### Discussion of Background

Various display devices for displaying images in TV, a monitor, a smart phone, a tablet PC and a notebook computer have been utilized. The display devices includes a display panel having multiple light emitting elements or liquid crystals for implementing images and transistors for controlling each light emitting element or liquid crystal so that the display devices can display desired images through the multiple light emitting element or the liquid crystals.

Technologies for a light emitting display device including a light-emitting diode as one of the display devices have been developed rapidly. The light emitting display device may be divided into an organic light emitting display device using organic luminescent materials and an inorganic light emitting display device using inorganic luminescent materials.

A display device typically includes a polarizing plate on a display surface so as to minimize external light reflection. Recently, extensive research and development efforts have been performed to improve reliability and image quality of the display devices.

The above information disclosed in this Background section is only for understanding of the background of the inventive concepts, and, therefore, it may contain information that does not constitute prior art.

### SUMMARY

A display device according to embodiments of the invention substantially obviates one or more of the problems arising from the limitations and disadvantages of the related art.

A display device according to one or more embodiments is capable of minimizing a reflection of an external light while maintaining or improving luminance and preventing lowered luminance.

A display device according to one or more embodiments is capable of minimizing stains and a rainbow mura caused by external light, light reflection from conductive materials such as a conductive film and/or electrode in a display panel, and/or refractive index differences among the films through which the light is passed through.

A display device according to one or more embodiments is capable of increasing an external light reflection path, improving external light re-absorption in a black matrix, and minimizing transmittance of external light including long wavelength in the black matrix.

A display device according to one or more embodiments is capable of improving flexibility and applicable to a foldable product.

A display device according to one or more embodiments is capable of obviating a polarizing member.

A display device according to one or more embodiments is capable of implementing low reflection and low power, thereby being environmentally friendly and pursuing ESG (Environmental, Social and Governance).

Additional features of the inventive concepts will be set forth in the description which follows, and in part will be apparent from the description, or may be learned by practice of the inventive concepts.

A display device according to an embodiment includes a substrate having an emission area and a non-emission area, a light-emitting diode disposed on the substrate correspondingly to the emission area, a touch sensor disposed on the light-emitting diode, an organic insulating layer disposed on the touch sensor, an inorganic buffer layer disposed on the organic insulating layer, and a black matrix disposed on the inorganic buffer layer correspondingly to the non-emission area, in which the organic insulating layer has a plurality of first uneven patterns on a surface thereof corresponding to the non-emission area, and the inorganic buffer layer has a plurality of second uneven patterns on a surface thereof corresponding to the non-emission area.

The first uneven patterns may include a plurality of first concave portions each of which has a wedge-shaped cross-section.

The first concave portions having the wedge-shaped cross-section may have a height greater than a width of each of the first concave portions.

The height of the first concave portions may be two to five times greater than the width of each of the first concave portions.

The first uneven patterns may include a plurality of first concave portions and a pitch between adjacent first concave portions among the first concave portions may be irregular.

The first uneven patterns may include a plurality of first concave portions and a width of each of the first concave portions may be irregular.

The inorganic buffer layer may have a refractive index different from a refractive index of the organic insulating layer.

The first uneven patterns and the second uneven patterns may be disposed to overlap the black matrix.

In another embodiment, the black matrix may include a plurality of third uneven patterns on a surface thereof.

The third uneven patterns may include a plurality of third concave portions each of which has a wedge-shaped cross-section.

The third concave portions having the wedge-shaped cross section may have a height greater than a width of each of the third concave portions.

The height of the third concave portions may be two to five times greater than the width of each of the third concave portions.

The third uneven patterns may include a plurality of third concave portions and a pitch between adjacent third concave portions among the third concave portions may be irregular.

The third uneven patterns may include a plurality of third concave portions and a width of each of the third concave portions may be irregular.

The first uneven patterns may include a plurality of first concave portions, the second uneven patterns include a plurality of second concave portions and the third uneven patterns include a plurality of third concave portions, and each of the first concave portions and the second concave portions may be positioned to be misaligned with the third concave portions.

The display device may further include a bank layer disposed outside of the light-emitting diode corresponding to the non-emission area.

The bank layer may include at least one of a black pigment and a black dye.

The display device may further include a driving thin film transistor disposed on the substrate and connected to the light-emitting diode, an encapsulation layer disposed on the light-emitting diode and the bank layer, and a color filter layer disposed on the encapsulation layer correspondingly to the emission area.

A side of the bank layer in contact with the light-emitting diode may extend toward the light-emitting diode than a side of the black matrix.

The driving thin film transistor may include an oxide semiconductor.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 illustrates a schematic circuit diagram of a display device according to one or more embodiments of the present disclosure.

FIG. 2 illustrates a schematic cross-sectional view of the display device in accordance with a first embodiment of the present disclosure.

FIGS. 3A and 3B are schematic diagrams illustrating components of an organic insulating layer, an inorganic buffer layer and a black matrix in the display device in accordance with the first embodiment of the present disclosure.

FIG. 4 is a schematic diagram illustrating that an external light reflected from a touch electrode is trapped within uneven patterns to minimize a reflection of the external light in the display device in accordance with the first embodiment of the present disclosure.

FIG. 5 illustrates a schematic cross-sectional view of a display device in accordance with a second embodiment of the present disclosure.

FIGS. 6A and 6B are schematic diagrams illustrating components of an organic insulating layer, an inorganic buffer layer and a black matrix in the display device in accordance with the second embodiment of the present disclosure.

FIG. 7 is a schematic diagram illustrating that an external light reflected from a touch electrode is trapped within uneven patterns to minimize a reflection of the external light in the display device in accordance with the second embodiment of the present disclosure.

FIG. 8 illustrates a schematic exploded perspective view of a display device in accordance with a third embodiment of the present disclosure.

FIG. 9 illustrates a schematic cross-sectional view of the display device in accordance with the third embodiment of the present disclosure.

FIGS. 10, 11, and 12 are photographs illustrating simulations of reflectance of an external light in a display device (FIG. 10) in which uneven patterns are disposed on the surfaces of an organic insulating layer and an inorganic buffer layer, a display device (FIG. 11) in which the depth of a black matrix is extended to a depth corresponding to the depth of the uneven patterns, and a display device (FIG. 12) in which the uneven patterns are not disposed on the surfaces of the organic insulating layer and the inorganic buffer layer, respectively.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In analyzing a component, an error range should be interpreted as being included even where there is no explicit description.

Reference will now be made in detail to aspects of the disclosure, examples of which are illustrated in the accompanying drawings. Wherever possible, the same reference numbers will be used throughout the drawings to refer to the same or like parts.

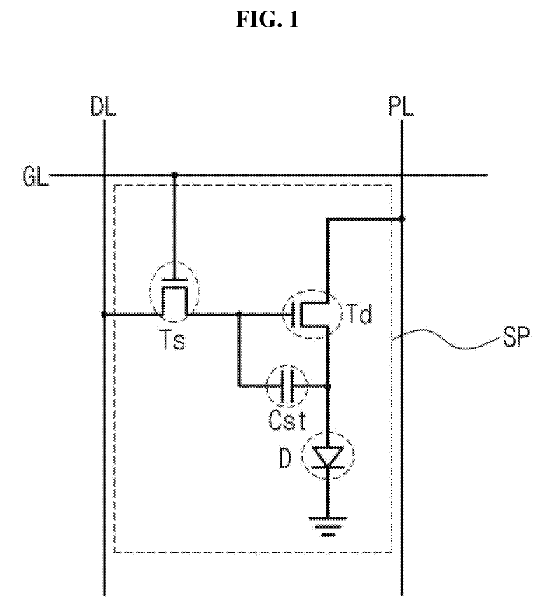

FIG. 1 illustrates a schematic circuit diagram of a light emitting display device according to one or more embodiments of the present disclosure.

Referring to FIG. 1, the display device according to an embodiment includes a gate line GL, a data line DL, and a power line PL crossing each other to define a sub-pixel region SP. A switching thin film transistor Ts, a driving thin film transistor Td, a storage capacitor Cst, and a light-emitting diode D may be disposed in the sub-pixel region SP. The sub-pixel region SP may include a first sub-pixel region, a second sub-pixel region, a third sub-pixel region, and optionally, a fourth sub-pixel region. For example, the first sub-pixel region may be a red (R) sub-pixel region, the second sub-pixel region may be a green (G) sub-pixel region, the third sub-pixel region may be a blue (B) sub-pixel region, and the fourth sub-pixel region may be a white (W) sub-pixel region but is not limited thereto.

The switching thin film transistor Ts is connected to the gate line GL and the data line DL. The driving thin film transistor Td and the storage capacitor Cst are connected between the switching thin film transistor Ts and the power line PL, and the light-emitting diode D is connected to the driving thin film transistor Td.

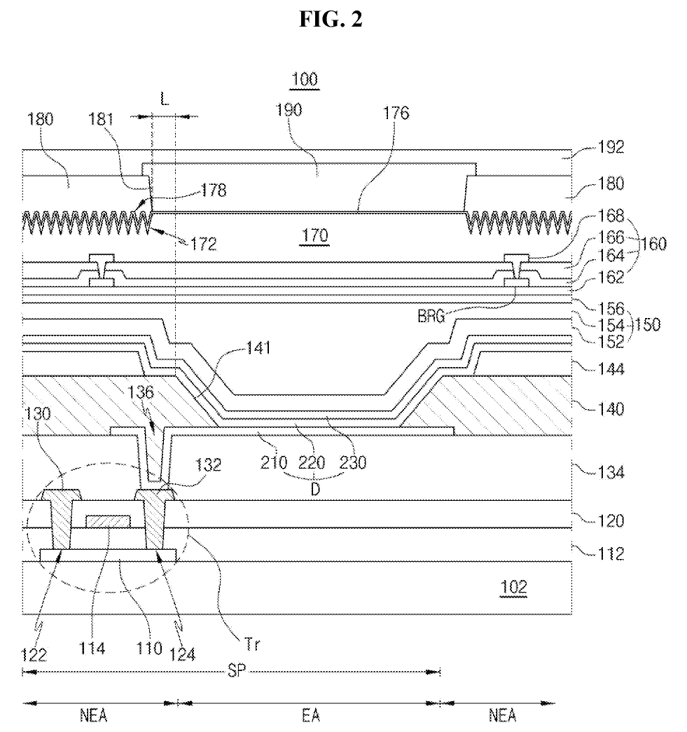

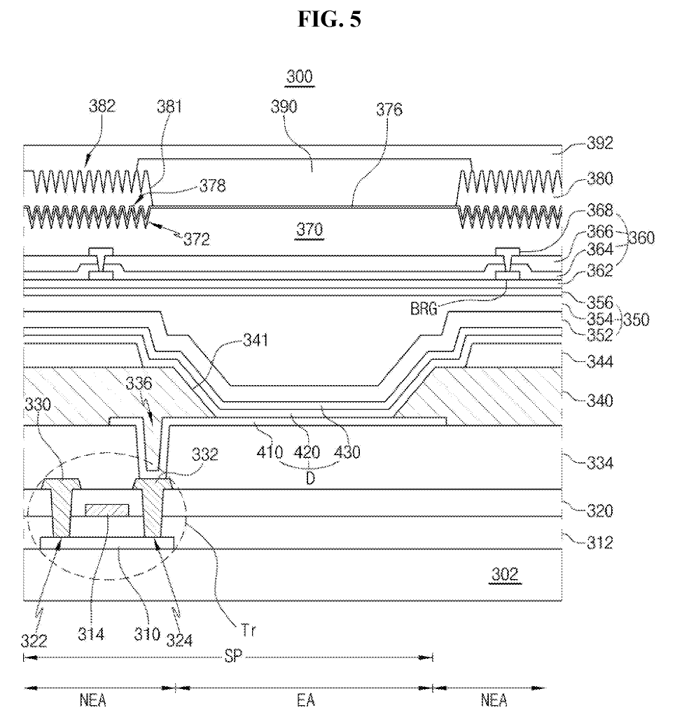

In the display device, when the switching thin film transistor Ts is turned on by a gate signal applied to the gate line GL, a data signal applied to the data line DL is applied a gate electrode 114 or 314 (FIG. 2 or FIG. 5) of the driving thin film transistor Td and one electrode of the storage capacitor Cst through the switching thin film transistor Ts.

The driving thin film transistor Td is turned on by the data signal applied to the gate electrode 114 or 314 so that a current proportional to the data signal is supplied from the power line PL to the light-emitting diode D through the driving thin film transistor Td. And then, the light- emitting diode D emits light having a luminance proportional to the current flowing through the driving thin film transistor Td. In this case, the storage capacitor Cst is charged with a voltage proportional to the data signal so that the voltage of the gate electrode 114 or 314 in the driving thin film transistor Td is kept constant during one frame. In this manner, the display device may display a desired image.

In one embodiment, each of the switching thin film transistor Ts and/or the driving thin film transistor Td may include a polycrystalline semiconductor material such as low temperature polycrystalline silicon (LTPS) and/or an oxide semiconductor, without being limited thereto. For example, the switching thin film transistor Ts and/or the driving thin film transistor Td may be a transistor of a low temperature polycrystalline and oxide (LPTO) type including the LPTS and the oxide semiconductor, but is not limited thereto. In another embodiment, the driving thin film transistor Td may be a transistor of a Complementary Metal Oxide Semiconductor (CMOS) type combining a p-Channel Metal Oxide Semiconductor (PMOS) and an n-Channel Metal Oxide Semiconductor (NMOS), but is not limited thereto.

### First Embodiment

FIG. 2 illustrates a schematic cross-sectional view of the display device according to a first embodiment of the present disclosure.

Referring to FIG. 2, a display device 100 includes a substrate 102, a light-emitting diode D disposed on the substrate 102, a black matrix 180 disposed on the light-emitting diode D, and optionally or additionally, a thin film transistor Tr disposed on the substrate 102 and/or a color filter layer 190 disposed on the light-emitting diode D.

The sub-pixel region SP (FIG. 1) including the red sub-pixel, the green sub-pixel, and the blue sub-pixel may be defined in the substrate 102. The sub-pixel region SP may further include the white sub-pixel. In addition, the substrate 102 may include an emission area EA and a non-emission area NEA disposed adjacently to the emission area EA or surrounds the emission area EA.

The substrate 102 may include, but is not limited to, a glass substrate, a flexible substrate, or a polymer plastics substrate. For example, the substrate 102 may be configured to have at least one of a polyimide (PI) substrate, a polyether sulfone (PES) substrate, a polyethylene naphthalate (PEN) substrate, a polyethylene terephthalate (PET) substrate, and a polycarbonate (PC) substrate.

The thin film transistor Tr is disposed on the substrate 102. In FIG. 2, the thin film transistor Tr is exemplarily illustrated as being disposed directly on the substrate 102. However, the inventive concepts are not limited thereto. In another embodiment, a first buffer layer may be disposed on the substrate 102 and the thin film transistor Tr may be disposed on the first buffer layer. For example, the first buffer layer may include, but is not limited to, silicon oxide (SiOₓ) and/or silicon nitride (SiNₓ,) (wherein 0 < x ≤ 2).

The thin film transistor Tr may include a semiconductor layer 110, a gate electrode 114, a source electrode 130, and a drain electrode 132. The thin film transistor Tr may be formed as the driving thin film transistor Td (FIG. 1).

The semiconductor layer 110 is disposed on the substrate 102. In one embodiment, the semiconductor layer 110 may include an oxide semiconductor material. For example, the oxide semiconductor may be selected from, but is not limited to, Indium Gallium Zinc oxide (IGZO), Indium Zinc Tin oxide (IZTO), Zinc Gallium Tin oxide (ZGTO), Zinc Tin oxide (ZTO), Zinc Gallium oxide (ZGO), Zinc oxide (ZnO), and combinations thereof. When the semiconductor layer 110 includes the oxide semiconductor material, a light shielding pattern may be disposed under the semiconductor layer 110. The light shielding pattern may prevent light from being incident on the semiconductor layer 110, thereby preventing or at least suppressing light-induced degradation of the semiconductor layer 110. In another embodiment, the semiconductor layer 110 may include a polycrystalline semiconductor. In this case, impurity may be doped to both sides of the semiconductor layer 110.

A gate insulating layer 112 may be disposed on the semiconductor layer 110 and cover the entire substrate 102. For example, the gate insulating layer 112 may include, but is not limited to, an inorganic insulating material such as silicon oxide (SiOₓ) and/or silicon nitride (SiNₓ) (wherein 0 < x ≤ 2).

The gate electrode 114 including a conductive material such as metal is disposed on the gate insulating layer 112, at a position corresponding to a center of the semiconductor layer 110. For example, the gate electrode 114 may include, but is not limited to, a metal component such as copper (Cu), molybdenum (Mo), titanium (Ti), aluminum (Al), gold (Au), and silver (Ag). The gate electrode 114 may have a mono-layer structure or a multi-layer structure. In FIG. 2, while the gate insulating layer 112 may be disposed on the entire substrate 102, in some embodiments, the gate insulating layer 112 may be patterned to have a shape that conforms to the shape of the gate electrode 114.

An interlayer insulating layer 120 is disposed on the gate electrode 114 and may cover the entire substrate 102. For example, the interlayer insulating layer 120 may include, but is not limited to, an inorganic insulating material such as silicon oxide (SiOₓ) and silicon nitride (SiNₓ) (wherein 0 < x ≤ 2) or an organic insulating material such as benzocyclobutene and/or photo-acryl.

The interlayer insulating layer 120 has first and second semiconductor contact holes 122 and 124 that expose or do not cover the both sides of the semiconductor layer 110. The first and second semiconductor contact holes 122 and 124 are spaced apart from the gate electrode 114 at both sides of the gate electrode 114. In FIG. 2, the first and second semiconductor contact holes 122 and 124 are exemplarily illustrated as being disposed in both of the interlayer insulating layer 120 and the gate insulating layer 112. However, the inventive concepts are not limited thereto. In another embodiment, when the gate insulating layer 112 is patterned to have a shape that conforms to the shape of the gate electrode 114, the first and second semiconductor contact holes 122 and 124 may be formed only in the interlayer insulating layer 120.

The source electrode 130 and the drain electrode 132 including a conductive material such as metal component are disposed on the interlayer insulating layer 120. The source electrode 130 and the drain electrode 132 are spaced apart from each other with the gate electrode 114 therebetween and electrically contact both sides of the semiconductor layer 110 through the first and second semiconductor contact holes 122 and 124. In one embodiment, the source electrode 130 may be an input electrode electrically connected to a high potential driving power and the drain electrode 132 may be an output electrode electrically connected to a switch circuit but is not limited thereto. The amount of current flowing to the light-emitting diode D may be controlled by voltage differences between the gate electrode 114 and the source electrode 130.

For example, the source electrode 130 and the drain electrode 132 may include, but is not limited to, the metal component such as copper (Cu), molybdenum (Mo), titanium (Ti), aluminum (Al), gold (Au), and/or silver (Ag). The source electrode 130 and the drain electrode 132 may have a mono-layer structure or a multi-layer structure.

In FIG. 2, the thin film transistor Tr is exemplarily illustrated as having a coplanar structure where the gate electrode 114, the source electrode 130, and the drain electrode 132 are disposed on the semiconductor layer 110. However, the inventive concepts are not limited thereto, and in another embodiment, the thin film transistor may have an inverted staggered structure where the gate electrode is disposed under the semiconductor layer and the source electrode, and the drain electrode are disposed on the semiconductor layer. In this case, the semiconductor layer may include amorphous silicon.

The thin film transistor Tr may be the driving thin film transistor Td (FIG. 1). For example, the driving thin film transistor Td may include the oxide semiconductor but is not limited thereto.

A planarization layer 134 is disposed on the source electrode 130 and the drain electrode 132 and may cover the entire substrate 102. The planarization layer 134 may be disposed to cover the thin film transistor Tr.

The planarization layer 134 has a flat surface and has a contact hole 136 that exposes or do not cover the source electrode 130 or the drain electrode 132. For example, the planarization layer 134 may include, but is not limited to, an inorganic insulating material such as silicon oxide (SiOₓ) and silicon nitride (SiNₓ) (wherein 0 < x ≤ 2) or an organic insulating material such as benzocyclobutene and/or photo-acryl.

The light-emitting diode D is disposed on the planarization layer 134 correspondingly to the emission area EA. The light-emitting diode D includes a first electrode 210 disposed on the planarization layer 134 and electrically connected to the source electrode 130 or the drain electrode 132, and an emissive layer 220 and a second electrode 230 that are laminated sequentially on the first electrode 210. For example, the light-emitting diode D may be positioned in each of the red sub-pixel, the green sub-pixel, and the blue sub-pixel and emit red light, green light, and blue light, respectively.

The first electrode 210 may be disposed separately in each sub-pixel region SP. The first electrode 210 may be an anode and include a conductive material with relatively high work function value, for example, a transparent conductive oxide (TCO). For example, the first electrode 210 may include, but is not limited to, Indium Tin oxide (ITO), Indium Zinc oxide (IZO), Indium Tin Zinc oxide (ITZO), Tin oxide (SnO), Zinc oxide (ZnO), Indium Copper oxide (ICO) and/or Aluminum Zinc oxide (AZO).

In one embodiment, the first electrode 210 may have a mono-layer structure of the transparent conductive oxide. In another embodiment, the first electrode 210 may have a bi-layer structure or a triple-layer structure and further include a reflective layer. In this case, the first electrode 210 may be a reflective electrode.

In one embodiment, the reflective layer may include, but is not limited to, silver (Ag), an alloy including silver (Ag) and at least one of palladium (Pd), copper (Cu), indium (In) and neodymium (Nd), and/or an aluminum-palladium-copper (APC) alloy. For example, the first electrode 210 may have a bi-layer structure of Ag/ITO or APC/ITO or a triple-layer structure of ITO/APC/ITO.

The bank layer 140 is disposed on the planarization layer 134 correspondingly to the non-emission area NEA and may cover the periphery of the first electrode 210. The bank layer 140 exposes or do not cover the center of the first electrode 210 corresponding to the sub-pixel region SP. For example, the bank layer 140 may include a light-blocking material such as a black material, a light-shielding material and/or a light-absorbing material. Alternatively, the bank layer 140 may include a material absorbing specific wavelength ranges.

For example, the light-blocking material may include a black colorant capable of absorbing light such as a black pigment and/or a black dye, and/or the light-shielding material. For example, the light-blocking material may include, but is not limited to, carbon black, carbon nanotube (CNT), graphene, organic black, a black dye, a perylene-containing material, an azo-containing material, a nano-based carbon material, a hybrid type of red (R) / green (G) / blue (B) pigments/dyes, a multiple thin-film material. In addition, the light-blocking material may include an organic material that may be oxidized and converted to black color in a post-baking process.

In another embodiment, the bank layer 140 may have a lamination structure where a color filter includes at least two colorants among a red color filtering material, a green color filtering material, and a blue color filtering material.

In one embodiment, a side 141 of the bank layer 140 that is contact with an outside of the light-emitting diode D may have a downwardly inclined cross-sectional shape toward the emissive layer 220. In particular, the side 141 of the bank layer 140 may have a cross-sectional shape, in which a width thereof gradually increases toward the first electrode 210, a tapered cross-sectional shape, but is not limited thereto.

The side 141 of the bank layer 140 may be curved with a predetermined curvature or may be extended downwardly without a curvature. For example, the side 141 of the bank layer 140 may form an angle between about 30^{o} and about 90^{o}, for example, about 45^{o} and about 90^{o}, with respect to the surface of the first electrode 210 but is not limited thereto. As the side 141 of the bank layer 140 has the tapered cross-sectional shape, the occurrence of a dead point in the light-emitting diode D may be minimized, and disconnection or lifting in the light-emitting diode D may be prevented.

The bank layer 140 may further include a binder resin capable of dispersing the light-blocking material. The binder resin of the bank layer 140 may include any photosensitive binder resin. For example, the binder resin in the bank layer 140 may include, but is not limited to, a (meth) acrylate-containing resin, an acryl-containing resin, a cardo-containing resin, an epoxy-containing resin, an amide-containing resin, a urethane-containing resin, an acrylamide-containing resin, an imide-containing resin, a fluorene-containing resin, a siloxane-containing resin, copolymer thereof, and a combination thereof.

The bank layer 140 may be disposed or arranged on the planarization layer 134 by coating a photosensitive composition including the binder resin; a solvent; the light-blocking material; and an additive, such as dispersant, on the peripheral surface of the first electrode 210 and the planarization layer 134 and then performing a photoresist (PR) process using a mask. For example, the bank layer 140 may be disposed on the peripheral area of the first electrode 210 and the planarization layer 134 through a negative PR process using the mask but is not limited thereto.

A column spacer 144 is disposed on the bank layer 140. The column spacer 144 may surround the emission area EA where the light-emitting diode D is disposed in each sub-pixel region SP. The column spacer 144 may include the same material as the bank layer 140. For example, the column spacer 144 may include the light-blocking or light-absorbing material and the binder resin dispersing the light-blocking or light-absorbing material.

For example, the column spacer 144 may have a cross-sectional shape, in which a width thereof gradually increases toward the bank layer 140 (a trapezoidal cross-sectional shape or a taper shape), or a cross-sectional shape where the width thereof gradually decreases toward the bank layer 140 (an inverted-trapezoidal cross-sectional shape or an inverted-taper shape), but is not limited thereto.

The emissive layer 220 is disposed on the first electrode 210. For example, the emissive layer 220 may have a mono-layer structure of an emitting material layer (EML). The EML may include an organic luminescent material or an inorganic luminescent material. In particular, the light emitting display device 100 may be an organic light emitting display device or an inorganic light emitting display device.

In the organic light emitting display device, the EML may include a host and a dopant as an emitter. For example, the EML may include a red host and a red dopant in the red sub-pixel, a green host and a green dopant in the green sub-pixel, and a blue host and a blue dopant in the blue sub-pixel. In the inorganic light emitting display device, the EML may include quantum dots as the inorganic luminescent material but is not limited thereto.

In another embodiment, the emissive layer 220 may have a multi-layer structure. For example, the emissive layer 220 may further include at least one of a hole injection layer (HIL), a hole transport layer (HTL), an electron blocking layer (EBL), a hole blocking layer (HBL), an electron transport layer (ETL), and an electron injection layer (EIL) in addition to the EML.

In one embodiment, the light-emitting diode D may emit white light in each of the red sub-pixel, the green sub-pixel, and the blue sub-pixel. For example, the emissive layer 220 of the light-emitting diode D may have a double-stack structure including a first emitting unit including a first emitting material layer, a second emitting unit including a second emitting material layer, and a charge generation layer (CGL) disposed between the first emitting unit and the second emitting unit. In another embodiment, the emissive layer 220 of the light-emitting diode D may have a triple-stack structure further including a third emitting unit including a third emitting material layer and another charge generation layer between the second emitting unit and the third emitting unit.

The second electrode 230 is disposed on the substrate 102 onto which the emissive layer 220 is disposed. The second electrode 230 may be disposed on the entire display area and include a conductive material with relatively low work function value to function as a cathode. For example, the second electrode 230 may include, but is not limited to, aluminum (Al), magnesium (Mg), calcium (Ca), silver (Ag), and an alloy thereof such as magnesium silver alloy. The second electrode 230 may have a thin thickness to have a light-transmissive (semi-transmissive) property.

An encapsulation layer (encapsulation film) 150 is disposed on the second electrode 230 in order to prevent external oxygen and/or moisture from infiltrating to the light-emitting diode D. In one embodiment, the encapsulation layer 150 may have, but is not limited to, a lamination structure of a first inorganic insulating layer 152, an organic insulating layer 154, and a second inorganic insulating layer 156.

Each of the first inorganic insulating layer 152 and the second inorganic insulating layer 156 may include, but is not limited to, an inorganic insulating material such as silicon oxide (SiOₓ) and silicon nitride (SiNₓ) (wherein 0 < x ≤ 2). The organic insulating layer 154 may include, but is not limited to, an organic insulating material such as an epoxy resin, photo-acryl (or photosensitive acrylic polymer). The organic insulating layer 154 is disposed between the first inorganic insulating layer 152 and the second inorganic insulating layer 566. The organic insulating layer 154 may planarize a step formed thereunder and provide a flat surface.

A touch sensor (touch panel) 160 may be disposed on the encapsulation layer 150 to provide a sensing function. For example, the touch sensor 160 may include a bridge electrode or a connection electrode BRG and a touch electrode 168 and may further include a plurality of insulating layers and/or buffer layers.

In one embodiment, the touch sensor 160 may include a first touch buffer layer 162, a first touch insulating layer 164, a second touch insulating layer 166, and plurality of touch electrodes 168. In addition, the touch sensor 160 may further include a second touch buffer layer covering the second touch insulating layer 166 and the touch electrode 168.

The first touch buffer layer 162 is disposed on the second inorganic insulating layer 156 of the encapsulation layer 150. The first touch buffer layer 162 is disposed directly on the second inorganic insulating layer 156 to improve adhesion forces between the touch sensor 160 and the second inorganic insulating layer 156. For example, the first touch buffer layer 162 may improve the adhesion force between a metal layer such as the bridge electrode BRG and the second inorganic insulating layer 156.

The first touch buffer layer 162 may include an inorganic insulating material. For example, the first touch buffer layer 162 may include, but is not limited to, an inorganic insulating material selected from silicon oxide (SiOₓ), silicon nitride (SiNₓ,), aluminum oxide (AlOₓ) (wherein 0 < x ≤ 2), and a combination thereof.

The bridge electrode BRG is disposed on the first touch buffer layer 162, and the first touch insulating layer 164 may cover the bridge electrode BRG. The second touch insulating layer 166 is disposed on the first touch insulating layer 164, and the plurality of touch electrodes 168 may be disposed on the first and second touch insulating layers 164 and 166.

The bridge electrode BRG may be electrically connected to at least a portion of the plural touch electrodes 168. The first touch insulating layer 164 and the second touch insulating layer 166 may have a contact hole that exposes or do not cover the bridge electrode BRG. In this case, adjacent touch electrodes 168 may electrically contact the bridge electrode BRF through the contact hole to be electrically connected to each other.

The first touch insulating layer 164 and the second touch insulating layer 166 may include an inorganic insulating material and/or an organic insulating material. For example, each of the first and second touch insulating layers 164 and 166 may have a multi-layer structure where an organic layer and an inorganic layer are disposed alternately. For example, the first touch insulating layer 164 covering the bridge electrode BRG may include an inorganic insulating material and the second touch insulating layer 166 disposed on the first touch insulating layer 164 may include an organic insulating material but is not limited thereto.

For example, the first touch insulating layer 164 may include, but is not limited to, an inorganic insulating material selected from silicon oxide (SiOₓ), silicon nitride (SiNₓ,), aluminum oxide (AlOₓ) (wherein 0 < x ≤ 2), and a combination thereof. In another embodiment, the second touch insulating layer 166 may include, but is not limited to, a transparent organic insulating material selected from an acryl-containing resin, a polyester-containing resin, an epoxy-containing resin, a silicone-containing resin, and a combination thereof.

Each of the touch electrodes 168 may be disposed on the first touch insulating layer 164 and the second touch insulating layer 166 correspondingly to the bank layer 140 and/or a black matrix 180 to be described later. As the touch electrode 168 is covered by the black matrix 180, the touch electrode 168 is not visually recognized from the outside, and thereby minimizing deterioration in display quality, but the arrangement of the touch electrode 168 is not limited thereto. For example, the touch electrode 168 may include, but is not limited to, a transparent metal oxide such as ITO, IZO, ITZO, SnO, ZnO, ICO, and/or AZO.

In addition, the second touch buffer layer covering the plural touch electrodes 168 may be disposed. The second touch buffer layer protects the touch sensor 160 when the black matrix 180 and a color filter layer 190 are disposed on the touch sensor 160. For example, the second touch buffer layer may include, but is not limited to, the same inorganic material as the first touch buffer layer 162.

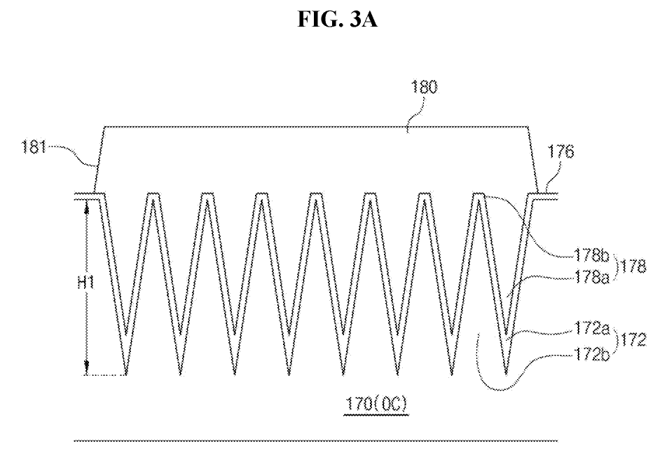

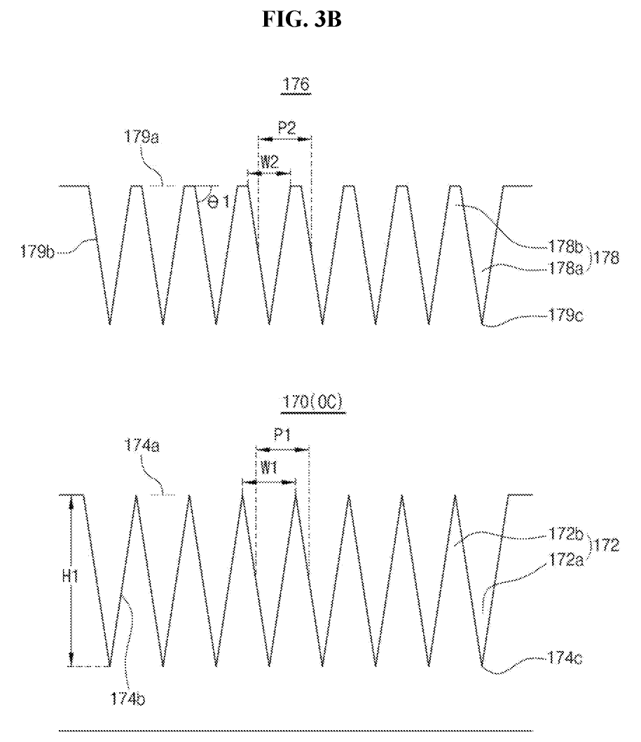

An organic insulating layer 170 may be disposed on the touch sensor 160 and may cover the entire substrate 102. The organic insulating layer 170 may be an over-coat layer OC. A plurality of first uneven patterns 172 are formed on a surface of the organic insulating layer 170. The plurality of first uneven patterns 172 may have a cross-sectional shape where a plurality of first concave portions 172a (FIGS. 3A and 3B) and a plurality of first convex portions 172b (FIGS. 3A and 3B) are alternately arranged. The detailed structure and the shape of the first uneven patterns 172 will be described later.

An inorganic buffer layer 176 is disposed on the organic insulating layer 170. A plurality of second uneven patterns 178 are formed on a surface of the inorganic buffer layer 176 along the plurality of first uneven patterns 172. The plurality of second uneven patterns 178 may have a cross-sectional shape where a plurality of second concave portions 178a (FIGS. 3A and 3B) and a plurality of second convex portions 178b (FIGS. 3A and 3B) are alternately arranged. The detailed structure and the shape of the second uneven patterns 178 will be described later.

In FIG. 2, the organic insulating layer 170 and the inorganic buffer layer 176 are exemplarily illustrated as being separated from the touch sensor 160. However, the inventive concepts are not limited thereto. In another embodiment, the organic insulating layer 170 and/or the inorganic buffer layer 176 may be a part of the touch sensor 160.

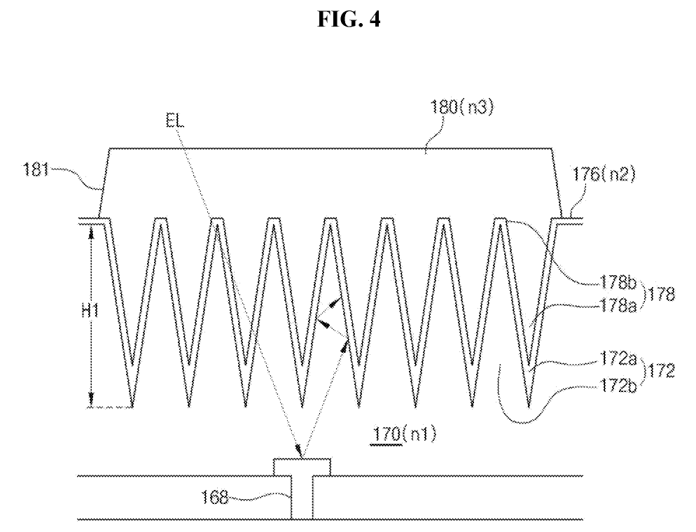

The black matrix 180 and the color filter layer 190 are disposed on the inorganic buffer layer 176. The black matrix 180 and the color filter layer 190 may minimize or at least reduce deterioration of the visibility and contrast ratio of the display device 100 caused by an external light EL (FIG. 4), while maintaining high luminance of light emitted from the light-emitting diode D.

The black matrix 180 is disposed correspondingly to the non-emission area NEA on the inorganic buffer layer 176. The black matrix 180 may have an opening corresponding to the light-emitting diode D. In one embodiment, the black matrix 180 may include a light-shielding material or a light-absorbing material such as a black resin, a black dye, and/or a black pigment. For example, the black matrix 180 may include, but is not limited to, an epoxy-containing photosensitive binder resin and carbon black. Alternatively, in some embodiments, another color filter layer including a red (R), green (G), and/or blue (B) colorants may be laminated on the black matrix 180.

In one embodiment, the bank layer 140 disposed correspondingly to the non-emission area NEA outside of the light-emitting diode D may extend further to the emission area EA relative to the black matrix 180. The side 141 of the bank layer 140 adjacently to the emission area EA covering the first electrode 210 may be disposed closer to the emission area EA than a side 181 of the black matrix 180 that is adjacent to the emission area EA, where the color filter layer 190 is disposed, thereby providing a ‘Pull-back’ structure.

In particular, compared to the side 181 of the black matrix 180 adjacent to the emission area EA, the side 141 of the bank layer 140 adjacent to the emission area EA may extend further toward the emission area EA by a protrusion length L. As used herein, the term “Pull-back distance” may be used for the separation distance L between the side 181 of the black matrix 180 adjacent to the emission area EA and the side 141 of the bank layer 140 adjacent to the emission area EA. By introducing such a Pull-back structure, the viewing angle luminance and color viewing angle properties of the display device 100 may be improved.

The color filter layer 190 is disposed to correspond to the openings of the black matrix 180. In particular, the color filter layer 190 is disposed on the encapsulation layer 150 or the touch sensor 160 correspondingly to the emission area EA. When the sub-pixel region SP includes the red sub-pixel, the green sub-pixel, and the blue sub-pixel, the color filter layer 190 may include a red color filter pattern corresponding to the red sub-pixel, a green color filter pattern corresponding to the green sub-pixel; and a blue color filter pattern corresponding to the blue sub-pixel.

The red color filter pattern may include at least one of a red dye and a red pigment. The green color filter pattern may include at least one of a green dye and a green pigment. The blue color filter pattern may include at least one of a blue dye and a blue pigment.

A first insulating layer 192 may be disposed on the black matrix 180 and the color filter layer 190 and cover the entire substrate 102. In one embodiment, the first insulating layer 192 may be an over-coat layer. The first insulating layer 192 may include an inorganic insulating material and/or an organic insulating material. For example, the first insulating layer 192 may include, but is not limited to, an organic insulating material, such as an epoxy-containing resin and/or photo-acryl, and/or an inorganic insulating material selected from silicon nitride (SiNₓ), aluminum oxide (AlOₓ) (wherein 0 < x ≤ 2) and a combination thereof. Alternatively, or additionally, a second insulating layer may be disposed on the first insulating layer 192.

The black matrix 180 including the light-blocking material is disposed on the touch sensor 160 in the non-emission area NEA. However, because the light-blocking material applied to the black matrix 180 exhibits increased light transmittance at long wavelengths, light refracted from the surface of the touch sensor 160 may not be completely blocked. Accordingly, there is a problem that the touch electrode 168 is visually recognized from the outside. According to embodiments of the invention, external light reflection is reduced by forming the plurality of uneven patterns 172 and 178 with a micro-texture structure on the touch sensor 160.

As described above, the plurality of first uneven patterns 172 are positioned on the surface of the organic insulating layer 170 disposed between the touch sensor 160 and the black matrix 180 (or between the touch sensor 160 and the color filter layer 190), and the plurality of second uneven patterns 178 are positioned on the surface of the inorganic buffer layer 176. By forming the plurality of first and second uneven patterns 172 and 178 each of which may have irregular shapes, external light absorbance area in the black matrix 180 may be increased. In addition, by arranging the plurality of first and second uneven patterns 172 and 178, incidence of external light into the light-emitting diode D and reflection of external light from the touch electrode 168 may be minimized. Accordingly, re-absorption of external light by the black matrix 180 may be maximized, thereby preventing the mura or stains caused by external light reflection.

In one embodiment, the plurality of first and second uneven patterns 172 and 178 may be extended to a peripheral area of the color filter layer 190. In this case, the external light incident to the peripheral area of the color filter layer 190 may be absorbed by the black matrix 180 due to the plurality of first and second uneven patterns 172 and 178, and the mura or the stains caused by external light reflection may be further minimized.

The arrangements and the structures of the organic insulating layer, the inorganic buffer layer, the plural uneven patterns, and the black matrix according to the first embodiment will be described in detail. FIGS. 3A and 3B are schematic diagrams illustrating components of an organic insulating layer, an inorganic buffer layer, and a black matrix in the display device in accordance with the first embodiment of the present disclosure. FIG. 4 is a schematic diagram illustrating that an external light reflected from a touch electrode is trapped within uneven patterns to minimize a reflection of the external light in the display device in accordance with the first embodiment of the present disclosure.

Referring to FIGS. 3A, 3B, and 4, the plurality of first uneven patterns 172 are arranged on the surface of the organic insulating layer 170, and the plurality of second uneven patterns 178 are arranged on the surface of the inorganic buffer layer 176 that is disposed on the organic insulating layer 170. The plurality of second uneven patterns 178 may be disposed along the plurality of first uneven patterns 172. The plurality of first and second uneven patterns 172 and 178 are positioned correspondingly to the non-emission area NEA on the surface of the organic insulating layer 170 and the inorganic buffer layer 176, respectively. In one embodiment, each of the plurality of the first and second uneven patterns 172 and 178 may be arranged to overlap with the black matrix 180.

The plurality of first uneven patterns 172 may include a plurality of first concave portions or first grooves 172a corresponding to valleys and a plurality of first convex portions or first flattening portions 172b corresponding to peaks, respectively, which are alternately positioned. The plurality of second uneven patterns 178 include a plurality of second concave portions 178a corresponding to the plurality of first concave portions 172a and a plurality of second convex portions 178b corresponding to the plurality of first convex portions 172b, respectively, which are alternately positioned.

In one embodiment, each of the plurality of first concave portions 172a and the plurality of second concave portions 178a may have a wedge-shaped cross-section, of which widths W1 and W2 gradually narrow toward the lower ends 174c and 179c, respectively. In accordance to the shape of the first and second concave portions 172a and 178a, each of the plurality of first convex portions 172b and the plurality of second convex portions 178b may have a wedge-shaped cross-section, of which widths W1 and W2 gradually narrow toward the upper end. In another embodiment, each of the plurality of first concave portions 172a and the plurality of second concave portions 178a may have, but is not limited to, an approximate U-shaped cross-section, a trapezoidal cross-section with an open upper end, an inverted trapezoidal cross-section with an open lower end, and/or a rectangular cross-section with an open upper surface.

A depth or height H1 of the first concave portion 172a and/or the second concave portion 178a may be larger than the widths W1 and W2 of bottom sides 174a and 179a corresponding to the vertices 174c and 179c at the first concave portion 172a and/or the second concave portion 178a, which may have the wedge-shaped cross-section. For example, the height H1 of the first concave portion 172a and/or the second concave portion 178a may be two times to five times larger than the widths W1 and W2 of the bottom sides 174a and 179a of the first concave portion 172a and/or the second concave portion 178a. In another embodiment, both sides 174b and 179b of the first concave portion 172a and/or the second concave portion 178bmay be inclined downwardly at an angle θ1 equal to or larger than about 60^{o} with respect the bottom sides 174a and 179a of the first concave portion 172a and the second concave portion 178a but is not limited thereto. As such, when the inorganic buffer layer 176 is interposed between the organic insulating layer 170 and the black matrix 180 according to an embodiment, a lower surface of the inorganic buffer layer 176 in the non-emission area NEA, on which the second uneven patterns 178 are formed, may be disposed at a lower elevation than an upper surface of the organic insulating layer 170 in the emission area EA.

In this case, the external light EL reflected from the touch electrode 168 is efficiently trapped within the first convex portions 172b and/or the second convex portions 178b defined by both sides 174b and 179b of the first concave portions 172a and/or the second concave portions 178a, each of which has the wedge-shaped cross-section. The reflection path of the external light EL is increased and changed while the external light EL is repeatedly reflected in the first convex portion 172b and/or the second convex portion 178b. In this manner, the amount of the external light EL absorbed into the black matrix 180 may be increased, and the amount of the external light EL passing through the black matrix 180 may be minimized. Accordingly, the stains caused by the reflection of the external light EL may be prevented.

The plurality of second uneven patterns 178 are positioned on the surface of the inorganic buffer layer 176 including the inorganic material, which has a relatively smooth surface than the organic material. Each of the second concave portions 178a of the second uneven patterns 178 may have the wedge-shaped cross-section with the acute vertex 179c. The external light EL incident to the inorganic buffer layer 176 may be efficiently reflected on the smooth surface of the inorganic buffer layer 176.

The depth or height H1 of each of the first and second concave portions 172a and 178a constituting the plurality of first uneven patterns 172 and the second uneven patterns 178, and the widths W1 and W2 of the bottom sides 174a and 179a of the first and second concave portions 172a and 178a and/or the first and second convex portions 172b and 178b, each of which may have the wedge-shaped cross-section, may have a textured structure with a micrometer dimension, respectively. In one embodiment, the widths W1 and/or W2 of the bottom sides 174a and 179a of the first and second concave portions 172a and 178a and/or the first and second convex portions 172b and 178b may be greater than wavelengths of visible light band. For example, the depth or height H1 of the first and second concave portions 172a and 178a and the widths W1 and W2 of the first and second concave portions 172a and 178a may be, but is not limited to, about 1 micrometer to about 10 micrometers, for example, about 1 micrometer to about 5 micrometers, respectively.

In another embodiment, the depth or height H1 of the first and second concave portions 172a and 178a may be greater than the widths W1 and/or W2 of the bottom sides 174a and 179a facing the vertices 174c and 179c in the first and second concave portions 172a and 178a with the wedge-shaped cross-section. For example, the height H1 of the first and second concave portions 172a and 178a may be two times to five times greater than the widths W1 and/or W2 of the bottom sides 174a and 179a of the first and second concave portions 172a and 178a. In this case, the external light EL incident to the display device 100 and reflected from the touch electrode 168 is efficiently trapped within the first and second convex portions 172b and 178b defined by both sides 174a and 179b of the first and second concave portions 172a and 178a so that the external light EL may be re-absorbed in the black matrix 180. Accordingly, the stains caused by the reflection of the external light EL may be prevented.

In FIGS. 3A, 3B and 4, each of the first concave portions 172a and the first convex portions 172b constituting the first uneven patterns 172, and each of the second concave portions 178a and the second convex portions 178b constituting the second uneven pattern 178, are exemplarily illustrated as having a regular shape in the non-emission area NEA, respectively. However, the inventive concepts are not limited thereto. In another embodiment, each of the first concave portions 172a and/or each of the first convex portions 172b constituting the first uneven patterns 172 may have an irregular of different shape. For example, each of the first concave portions 172a and/or each of the first convex portions 172b may be spaced apart from the adjacent first concave portion 172a and/or the first convex portion 172b with an irregular or different separation distance. In addition, each of the second concave portions 178a and/or each of the second convex portions 178b constituting the second uneven patterns 178 may have an irregular of different shape. For example, each of the second concave portions 178a and/or each of the second convex portions 178b may be spaced apart from the adjacent second concave portion 178a and/or the second convex portion 178b with an irregular or different separation distance.

In one embodiment, the widths W1 and/or W2 corresponding to the bottom sides 174a and 179a of each of the first and second concave portions 172a and 178a constituting the first and second uneven patterns 172 and 178 may be constituted randomly or differently. Pitches P1 and/or P2 between adjacently positioned first and second concave portions 172a and 178a constituting the first and second uneven patterns 172 and 178 may be constituted randomly or differently. In this case, the external light EL reflected from the touch electrode 168 may be more efficiently trapped within the first and second convex portions 172b and 178b defined by the sides 174b and 179b of the first and second concave portions 172a and 178a.

The organic insulating layer 170 may have a first refractive index n1, the inorganic buffer layer 176 may have a second refractive index n2, and the black matrix 180 may have a third refractive index n3. Both the organic insulating layer 170 and the black matrix 180 may include the photosensitive binder resin. The first refractive index n1 of the organic insulating layer 170 may be substantially the same as the third refractive index n3 of the black matrix 180. For example, each of the first refractive index n1 of the organic insulating layer 170 and the third refractive index n3 of the black matrix 180 may be, but is not limited to, about 1.5 to about 1.7, for example, about 1.55 to about 1.65.

In one embodiment, each of the organic insulating layer 170 and the black matrix 180 may include the binder resin such as the photosensitive binder resin. The binder resin that may be employed in the organic insulating layer 170 and the black matrix 180 may be any photosensitive binder resin that may be applied to the PR process. For example, the binder resin that may be employed in the organic insulating layer 170 and the black matrix 180 may independently include, but is not limited to, a (meth) acrylate-containing resin, an acryl-containing resin, a cardo-containing resin, an epoxy-containing resin, an amide-containing resin, a urethane-containing resin, an acrylamide-containing resin, an imide-containing resin, a fluorene-containing resin, a siloxane-containing resin, a copolymer thereof, and/or a combination thereof.

In another embodiment, the first refractive index n1 of the organic insulating layer 170 may be different from the second refractive index n2 of the inorganic buffer layer 176. For example, the second refractive index n2 of the inorganic buffer layer 176 may be greater than the first refractive index n1 of the organic insulating layer 170. In this case, the external light EL reflected from the touch electrode 168 enters the black matrix 180 through the organic insulating layer 170 and the inorganic buffer layer 176 and then can be efficiently absorbed by the light-blocking material dispersed in the black matrix 180.

In addition, when the first refractive index n1 of the organic insulating layer 170 is configured to be different from the second refractive index n2 of the inorganic buffer layer 176, the external light EL, which is reflected from the touch electrode 168 and trapped within the first and second convex portions 172b and 178b, is reflected prior to passing through the organic insulating layer 170 and the inorganic buffer layer 176, so that the light path of the external light EL may be changed. Accordingly, the diffraction stains caused by the reflection of the external light EL may be prevented and the external light EL may be efficiently absorbed by the light-blocking material in the black matrix 180.

In one embodiment, the second refractive index n2 of the inorganic buffer layer 176 may be greater than the first refractive index n1 of the organic insulating layer 170 by about 0.05 to about 0.3. For example, the second refractive index n2 of the inorganic buffer layer 176 may be, but is not limited to, more than about 1.7 to about 2.0, for example, more than about 1.70 to about 1.9.

The inorganic buffer layer 176 may include an inorganic oxide and/or an inorganic nitride. For example, the inorganic buffer layer 176 may include, but is not limited to, an inorganic insulating material selected form silicon oxide (SiOₓ), silicon nitride (SiNₓ), aluminum oxide (AlOₓ) (wherein 0 < x ≤ 2), and a combination thereof.

The plurality of first uneven patterns 172 may be positioned on the surface of the organic insulating layer 170 corresponding to the non-emission area NEA by arranging photomasks on the touch sensor 160 and performing a negative PR process when disposing the organic insulating layer 170. The plurality of first uneven patterns 172 may be formed using a dry etching and/or a wet etching. The width W1 of the bottom side 174a of the first concave portion 172a corresponding to the etching area, and/or the pitch P1 between the adjacent first concave portions 172a may be adjusted by controlling the sizes and arrangements of the photomasks.

The inorganic buffer layer 176 with the plurality of second uneven patterns 178 with the smooth surface is formed by depositing the inorganic buffer layer 176 along the first uneven patterns 172 on the surface of the organic insulating layer 170 with the first uneven patterns 172 corresponding to the non-emission area NEA. The black matrix 180 is disposed on the inorganic buffer layer 176 with the second uneven patterns 178 by applying the PR process.

In general, an ambient light diffraction mura due to the step difference caused by the thin film transistor Tr may occur. In addition, when the diffraction of the reflected external light EL is further enhanced by the color filter layer 190, a rainbow mura may occur due to the interference between adjacent sub-pixel regions SPs. The rainbow mura may also occur due to the light reflection at the conductive material such as the conductive films and/or electrodes within the display panel, or the refractive index differences between the layers in which the light passes through.

However, according to embodiments, the plurality of uneven patterns 172 and 178 are positioned on the surface of the organic insulating layer 170 disposed on the touch sensor 160 and on the surface of the inorganic buffer layer 176 corresponding to the non-emission area NEA. In this manner, the surface area of the black matrix 180 capable of absorbing the external light EL increases significantly. The external light EL reflected from the touch electrode 168 is trapped within the first and second convex portions 172b and 178b, and the external light EL tramped in the convex portions 172b and 178b repeats reflection and re-absorption by the black matrix 180 so that the external light EL may be extinguished. Accordingly, it is possible to prevent the external light EL from being reflected to the outside of the display device 100.

According to the embodiments of the present disclosure, the content of the light-blocking material inside the black matrix 180 for reducing the reflection of external light EL in the non-emission area NEA is not increased. When the content of the light-blocking material in the black matrix 180 increases, a free volume in the finally cured black matrix 180 pattern increases. When the free space increases, the fume and outgas also increase when the black matrix 180 is cured. When verifying the reliability of the product, the amount of outgas due to the high-temperature treatment increases, making it vulnerable to reliability.

On the other hand, according to the embodiments of the present disclosure, since the content of the light-blocking particles in the black matrix 180 is not increased, the free volume and the amount of outgas are not increased. Accordingly, the process reliability of the black matrix 180 may be secured.

In addition, if the content of the light-blocking material increases in the black matrix 180, it is difficult to efficiently form the black matrix 180 pattern in the development process performed after exposure of the photoresist (PR) process. However, since the content of the light-blocking material in the black matrix 180 does not increase according to the embodiments in the present disclosure, good process reliability may be secured when forming the black matrix 180.

### Second Embodiment

FIG. 5 illustrates a schematic cross-sectional view of a display device in accordance with a second embodiment of the present disclosure.

Referring to FIG. 5, a display device 300 in accordance with the second embodiment includes a substrate 302 having the emission area EA and the non-emission area NEA, a light emitting diode D disposed on the substrate 302, a black matrix 380 disposed on the light emitting diode D, and optionally, a thin film transistor Tr and/or a color filter layer 390 disposed on the substrate 302.

The sub-pixel region SP (FIG. 1) including the red sub-pixel, the green sub-pixel, the blue sub-pixel, and optionally, the white sub-pixel may be defined in the substrate 302.

The thin film transistor Tr is disposed on the substrate 302. The thin film transistor Tr includes a semiconductor layer 310, a gate electrode 314, a source electrode 330, and a drain electrode 332. The thin film transistor Tr may be the driving thin film transistor Td shown in FIG. 1.

The thin film transistor Tr may be disposed directly on the substrate 302, or on a buffer layer that may be disposed on the substrate 302. In one embodiment, the semiconductor layer 310 may include, but is not limited to, the oxide semiconductor.

A gate insulating layer 312 may be disposed on the semiconductor layer 310 and cover the entire substrate 302. The gate electrode 314 including a conductive material is disposed on the gate insulating layer 312 corresponding to the center of the semiconductor layer 310. The gate insulating layer 312 may be patterned as same as the gate electrode 314.

An interlayer insulting layer 320 is disposed on the gate electrode 314. The interlay insulating layer 320 may have first and second semiconductor contact holes 322 and 324 exposing both sides of the semiconductor layer 310. The first and second semiconductor contact holes 322 and 324 may be spaced apart from the gate electrode 314 at both sides of the gate electrode 314.

The source electrode 330 and the drain electrode 332 including a conductive material such as metal are disposed on the interlayer insulating layer 320. The source electrode 330 and the drain electrode 332 are spaced apart from each other with respect to the gate electrode 314 and electrically contact both sides of the semiconductor layer 310 through the first and second semiconductor contact holes 322 and 324.

A planarization layer 334 is disposed on the source electrode 330 and the drain electrode 332 and may cover the entire substrate 302. The planarization layer 334 has a contact hole 336 exposing the source electrode 330 or the drain electrode 332 of the thin film transistor Tr.

The light emitting diode D includes a first electrode 410 disposed on the planarization layer 334 and electrically connected to the source electrode 330 or the drain electrode 332 of the thin film transistor Tr, an emissive layer 420 and a second electrode 430 which are laminated sequentially on the first electrode 410.

A bank layer 340 covering a periphery of the first electrode 410 is disposed on the planarization layer 334 corresponding to the non-emission area NEA. A side 341 of the bank layer 340 may contact a side of the light emitting diode D. For example, the side 341 of the bank layer 340 may have a tapered shape but is not limited thereto.

A column spacer 344 is disposed on the bank layer 340. The column spacer 344 may have a cross-sectional shape where the width gradually increases toward the bank layer 340 (a trapezoidal cross-sectional shape or a taper shape), or a cross-sectional shape where the width gradually decreases toward the bank layer 340 (an inverted-trapezoidal cross-sectional shape or an inverted-taper shape) but is not limited thereto.

An encapsulation layer 350 is disposed on the second electrode 430 in order to prevent external oxygen and/or moisture form infiltrating to the light emitting diode D. The encapsulation layer 350 may have a lamination structure of a first inorganic insulating layer 352, an organic insulating layer 354 and a second inorganic insulating layer 356 but is not limited thereto.

A touch sensor 360 is disposed on the encapsulation layer 350. For example, the touch sensor 360 may include a first touch buffer layer 362, a bridge electrode BRG disposed on the first touch buffer layer 362 corresponding to the non-emission area NEA, a first touch insulating layer 364 disposed on the bridge electrode BRG, a second touch insulating layer 366 disposed on the first touch insulating layer 364, and a plurality of touch electrodes 368 disposed on the second touch insulating layer 366 corresponding to the non-emission area NEA. Alternatively, or additionally, the touch sensor 360 may further include a second touch buffer layer covering the touch electrodes 368.

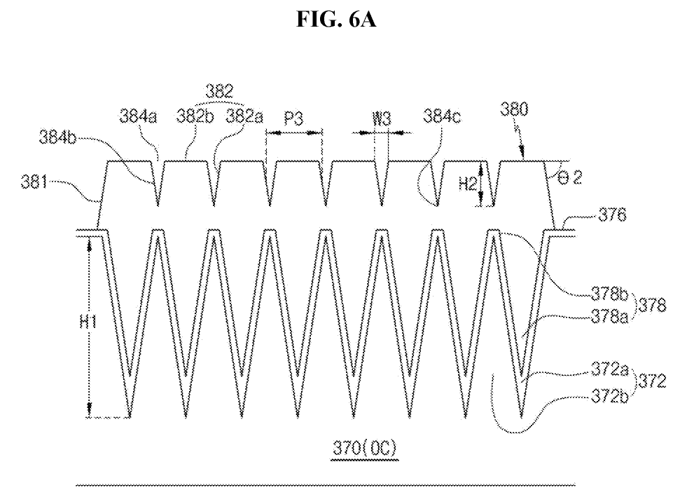

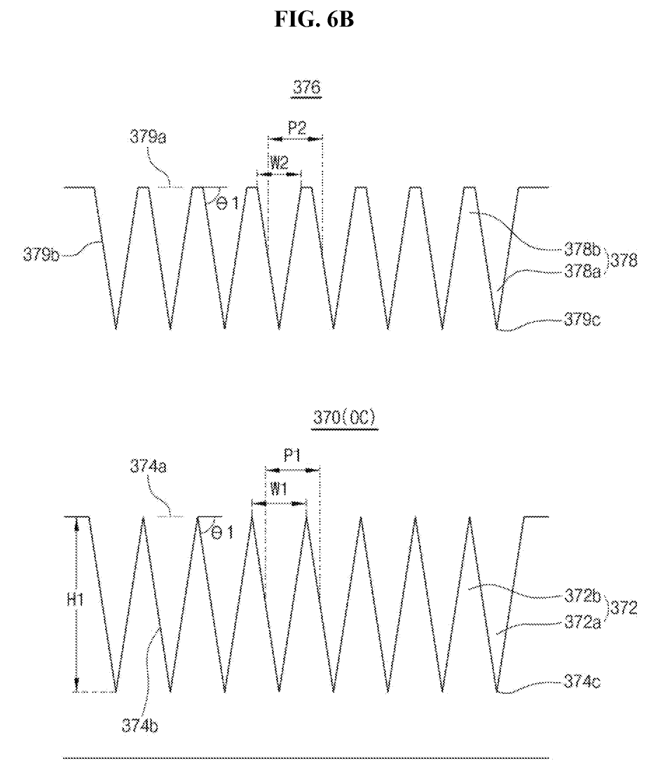

An organic insulating layer 370 is disposed on the touch sensor 360 and may cover the entire substrate 302. The organic insulating layer 370 may be an over-coat layer OC. A plurality of first uneven patterns 372 are arranged on the surface of the organic insulating layer 370. The plurality of first uneven patterns 372 may have a cross-sectional shape in which a plurality of first concave portions 372a (FIGS. 6A and 6B) and a plurality of first convex portions 372b (FIGS. 6A and 6B) are alternately arranged.

An inorganic buffer layer 376 is disposed on the organic insulating layer 370. A plurality of second uneven patterns 378 are arranged on the surface of the inorganic buffer layer 376 along the first uneven patterns 372. The plurality of second uneven patterns 378 may have a cross-sectional shape in which a plurality of second concave portions 378a (FIGS. 6A and 6B) and a plurality of second convex portions 378b (FIGS. 6A and 6B) are alternately arranged.

In FIG. 5, the organic insulating layer 370 and the inorganic buffer layer 376 are exemplarily illustrated as being separate from the touch sensor 360. However, the inventive concepts are not limited thereto. In another embodiment, the organic insulating layer 370 and/or the inorganic buffer layer 376 may be a part of the touch sensor 360.

A black matrix 380 is disposed on the inorganic buffer layer 376 corresponding to the non-emission area NEA. In the second embodiment, a plurality of third uneven patterns 382 are arranged on the surface of the black matrix 380. The plurality of third uneven patterns 382 may have a cross-sectional shape in which a plurality of third concave portions 382a (FIGS. 6A and 6B) and a plurality third convex portions 382b (FIGS. 6A and 6B) are alternately arranged.

A color filter layer 390 is disposed on the inorganic buffer layer 376 corresponding to the emission area EA. A first insulating layer 392 or an over-coat layer OC is disposed on the black matrix 380 and the color filter layer 390, and a second insulating layer may be disposed on the first insulating layer 392.

In one embodiment, the side 341 of the bank layer 340 adjacent to the emission area EA may be further extended to the emission area EA than a side 381 of the black matrix 380 adjacent to the emission area EA so as to have the “Pull-back structure”, but is not limited thereto.

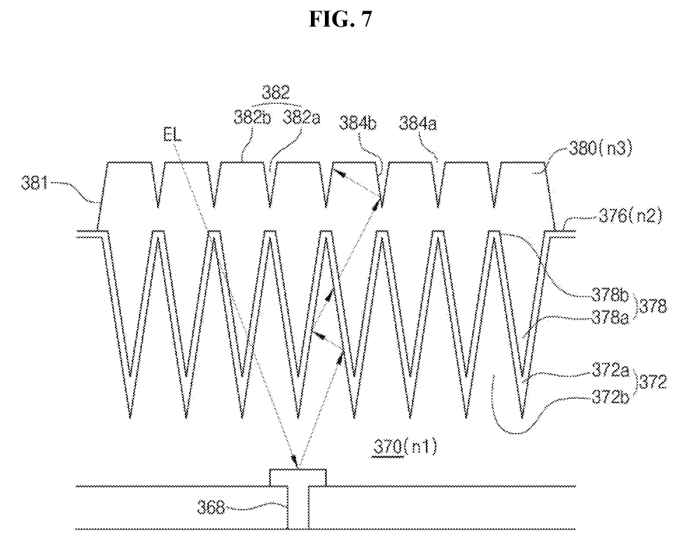

The arrangements and structure of the organic insulating layer 370, the inorganic buffer layer 376, the uneven patterns 372 and 378, and the black matrix 380 will be described in more detail. FIGS. 6A and 6B are schematic diagram illustrating components of an organic insulating layer, an inorganic buffer layer, and a black matrix in the display device in accordance with the second embodiment of the present disclosure. FIG. 7 is a schematic diagram illustrating that an external light reflected from a touch electrode is trapped within uneven patterns to minimize a reflection of the external light in the display device in accordance with the second embodiment of the present disclosure.

Referring to FIGS. 6A, 6B and 7, the plurality of first uneven patterns 372 are positioned on the surface of the organic insulating layer 370 and the plurality of second uneven patterns 378 are positioned on the surface of the inorganic buffer layer 376 that is disposed on the organic insulating layer 370. The plurality of first and second uneven patterns 372 and 378 are positioned correspondingly to the non-emission area NEA on the surface of the organic insulating layer 370 and the inorganic buffer layer 376, respectively. In one embodiment, each of the plurality of the first and second uneven patterns 372 and 378 may overlap the black matrix 380.

The plurality of first uneven patterns 372 may include the plurality of first concave portions or first grooves 372a corresponding to valleys and the plurality of first convex portions or first flattening portions 372b corresponding to peaks, respectively, which are alternately arranged. The plurality of second uneven patterns 378 may include the plurality of second concave portions 378a corresponding to the plurality of first concave portions 372a and the plurality of second convex portions 378b corresponding to the plurality of first convex portions 372b, respectively, which are alternately arranged.

In one embodiment, each of the plurality of first concave portions 372a and the plurality of second concave portions 378a may have a wedge-shaped cross-section of which widths W1 and W2 gradually narrow toward the lower ends 374c and 379c, respectively. In accordance with the first and second concave portions 372a and 378a, each of the plurality of first convex portions 372b and the plurality of second convex portions 378b may have a wedge-shaped cross-section of which widths W1 and W2 gradually narrow toward the upper end. In another embodiment, each of the plurality of first concave portions 372a and the plurality of second concave portions 378a may have, but is not limited to, an approximate U-shaped cross-section, a trapezoidal cross-section with an open upper end, an inverted trapezoidal cross-section with an open lower end, and/or a rectangular cross-section with an open upper surface.

In the second embodiment, the plurality of third uneven patterns 382 are positioned on the surface of the black matrix 380. The plurality of third uneven patterns 382 may include a plurality of third concave portions 382a corresponding to valleys and a plurality of third convex portions 382b corresponding to peaks, which are alternately arranged.

In one embodiment, each of the plurality of third concave portions 382a may have a wedge-shaped cross-section of which width W3 gradually narrows toward the lower end, that is, the organic insulating layer 370 and the inorganic buffer layer 376. In accordance with the third concave portions 382a, each of the plurality of third convex portions 382b may have a wedge-shaped cross-section of which width W3 gradually narrows toward the upper end. In another embodiment, each of the plurality of third concave portions 382a may have, but is not limited to, an approximate U-shaped cross-section, a trapezoidal cross-section with an open upper end, an inverted trapezoidal cross-section with an open lower end, and/or a rectangular cross-section with an open upper surface.

The depth or height H1 of each of the first and second concave portions 372a and 378a constituting the plurality of first uneven patterns 372 and the second uneven patterns 378, the widths W1 and W2 of the bottom sides 374a and 379a of the first and second concave portions 372a and 378a and/or the first and second convex portions 372b and 378b, each of which may have the wedge-shaped cross-section, the depth or height H2 of each of the third concave portions 382a constituting the plurality of third uneven patterns 382 and/or the width W3 of the bottom side 384a of the third concave portions 382a, which may have the wedge-shaped cross-section, may have a textured structure with a micrometer dimension, respectively.

In one embodiment, the widths W1 and/or W2 of the bottom sides 374a and 379a of the first and second concave portions 372a and 378a and/or the first and second convex portions 372b and 378b, and/or the width W3 of the bottom side 384a of the third concave portions 382a and/or the third convex portions 382b may be greater than wavelengths of visible light band. For example, the depth or height H1 of the first and second concave portions 372a and 378a, the widths W1 and W2 of the bottom sides 374a and 379a in the first and second concave portions 372a and 378a, the height H2 of the third concave portions 382a and the width W3 of the bottom side 384a in the third concave portions 382a may be, but is not limited to, about 1 micrometer to about 10 micrometers, for example, about 1 micrometer to about 5 micrometers, respectively.

In another embodiment, the depth or height H1 of the first and second concave portions 372a and 378a may be greater than the widths W1 and/or W2 of the bottom sides 374a and 379a facing the vertices 374c and 379c in the first and second concave portions 372a and 378a with the wedge-shaped cross-section. For example, the height H1 of the first and second concave portions 372a and 378a may be two times to five times greater than the widths W1 and/or W2 of the bottom sides 374a and 379a of the first and second concave portions 372a and 378a.

In another embodiment, the depth or height H2 of the third concave portion 382a may be greater than the width W3 of the bottom side 384a facing the vertex 384c in the third concave portion 382a with the wedge-shaped cross-section. For example, the height H1 of the third concave portion 382a may be two times to five times greater than the width W3 of the bottom sides 384a of the third concave portion 382a. In another embodiment, both sides 374b, 379b, and 384b of the first concave portion 372a, the second concave portion 378a, and/or the third concave portion 382a may be inclined downwardly with an angle θ1 or θ2 equal to or larger than about 60^{o} with respect the bottom sides 374a, 379a, and 384a of the first concave portion 372a, the second concave portion 378a, and the third concave portion 382a, but is not limited thereto. As such, when the inorganic buffer layer 136 is interposed between the organic insulating layer 370 and the black matrix 380 according to an embodiment, a lower surface of the inorganic buffer layer 376 in the non-emission area NEA, on which the second uneven patterns 378 are formed, may be disposed at a lower elevation than an upper surface of the organic insulating layer 370 in the emission area EA.

The external light EL reflected from the touch electrode 368 is efficiently trapped within the first convex portions 372b and/or the second convex portions 378b defined by both sides 374b and 379b of the first concave portions 372a and/or the second concave portions 378a each of which has the wedge-shaped cross-section, and the third convex portion 382b defined by both sides 384b of the third convex portion 382a. The reflection path of the external light EL is increased and changed while the external light EL is repeatedly reflected in the first and second convex portions 372b and 378b, and the third convex portion 382b. As the amount of the external light EL absorbed into the black matrix 380 increases, the amount of the external light EL passing through the black matrix 380 may be minimized. Accordingly, the stains caused by the reflection of the external light EL may be prevented.

The plurality of second uneven patterns 378 are positioned on the surface of the inorganic buffer layer 376 with a relatively smooth surface. Each of the second concave portions 378a of the second uneven patterns 378 may have the wedge-shaped cross-section with the acute vertex 379c. The external light EL incident to the inorganic buffer layer 376 may be efficiently reflected on the smooth surface of the inorganic buffer layer 376.

In FIGS. 6A, 6B and 7, each of the first concave portions 372a and the first convex portions 372b, and each of the second concave portions 378a and the second convex portions 378b, are exemplarily illustrated as having a regular shape in the non-emission area NEA, respectively. However, the inventive concepts are not limited thereto. In another embodiment, each of the first concave portions 372a and/or each of the first convex portions 372b constituting the first uneven patterns 372 may have an irregular of different shape. For example, each of the first concave portions 372a and/or each of the first convex portions 372b may be spaced apart from the adjacent first concave portion 372a and/or the first convex portion 372b with an irregular or different separation distance. Each of the second concave portions 378a and/or each of the second convex portions 378b constituting the second uneven patterns 378 may have an irregular of different shape. Each of the second concave portions 378a and/or each of the second convex portions 378b may be spaced apart from the adjacent second concave portion 378a and/or the second convex portion 378b with an irregular or different separation distance. Each of the third concave portions 382a and/or each of the third convex portions 382b constituting the third uneven patterns 382 may have an irregular of different shape. Each of the third concave portions 382a and/or each of the third convex portions 382b may be spaced apart from the adjacent third concave portion 382a and/or the third convex portion 382b with an irregular or different separation distance.

In one embodiment, the widths W1 and/or W2 corresponding to the bottom sides 374a and 379a of each of the first and second concave portions 372a and 378a constituting the first and second uneven patterns 372 and 378 may be constituted randomly or differently. The width W3 corresponding to the bottom side 384a of the third concave portion 382a constituting the third uneven pattern 382 may be constituted randomly or differently. The pitches P1 and/or P2 between adjacently positioned first and second concave portions 372a and 378a constituting the first and second uneven patterns 372 and 378 may be constituted randomly or differently. A pitch P3 between adjacently positioned third concave portions 382a constituting the third uneven pattern 382 may be constituted randomly or differently.

In this case, the external light EL reflected from the touch electrode 368 may be more efficiently trapped within the first and second convex portions 372b and 378b defined by the sides 374b and 379b of the first and second concave portions 372a and 378a, as well as the third convex portion 382b defined by the side 384b of the third concave portion 382a.

The first refractive index n1 of the organic insulating layer 370 may be different from the second refractive index n2 of the inorganic buffer layer 376 but may be substantially the same as the third refractive index n3 of the black matrix 380. In this case, the external light EL reflected from the touch electrode 368 can be efficiently absorbed by the light-blocking material dispersed in the black matrix 380. In addition, the diffraction stains caused by the reflection of the external light EL may be minimized as the light path of the external light EL is changed.

The plurality of first uneven patterns 372 may be positioned on the surface of the organic insulating layer 370 corresponding to the non-emission area NEA by arranging photomasks on the touch sensor 360 and performing a negative PR process when forming the organic insulating layer 370. The plurality of first uneven patterns 372 may be formed using a dry etching and/or a wet etching. The width W1 of the bottom side 374a of the first concave portion 372a corresponding to the etching area, and/or the pitch P1 between the adjacent first concave portions 372a may be adjusted by controlling the sizes and arrangements of the photomasks.

The inorganic buffer layer 376 with the plurality of second uneven patterns 378 with the smooth surface is disposed by depositing the inorganic buffer layer 376 along the first uneven patterns 372 on the surface of the organic insulating layer 370 with the first uneven patterns 372 corresponding to the non-emission area NEA.

The black matrix 380 is disposed on the inorganic buffer layer 376 with the second uneven patterns 378 using the PR process. The plurality of third uneven patterns 382 may be positioned on the surface of the black matrix 380 corresponding to the non-emission area NEA by arranging photomasks on the inorganic buffer layer 376 with the second uneven patterns 378 and performing a negative PR process. The width W3 of the bottom side 384a of the third concave portion 382a corresponding to the etching area, and/or the pitch P3 between the adjacent third concave portions 382a may be adjusted by controlling the sizes and arrangements of the photomasks.

In some embodiments, the first uneven pattern 372 and the second uneven pattern 378, and the third uneven pattern 382 may be disposed to be misaligned with each other. More particularly, the first and second concave portions 372a and 378a of the first and second uneven patterns 372 and 378 may be disposed at positions not corresponding to the third concave portion 382a of the third uneven pattern 382. In addition, the first and second convex portions 372b and 378b of the first and second uneven patterns 372 and 378 may be disposed at positions not corresponding to the third convex portion 382b of the third uneven pattern 382.

For example, the first and second concave portions 372a and 378a of the first and second uneven patterns 372 and 378 may be disposed at positions corresponding to the third convex portion 382b of the third uneven pattern 382, respectively. The first and second convex portions 372b and 378b of the first and second uneven patterns 372 and 378 may be disposed at positions corresponding to the third concave portion 382a of the third uneven pattern 382, respectively. In this case, the external light EL is diffusely reflected in the first and second uneven patterns 372 and 378 as well as the third uneven patterns 384 and thereby minimizing the reflection of the external light EL and maximizing the re-absorption of the external light EL in the black matrix 380.

The first and second uneven patterns 372 and 378 are positioned on surfaces corresponding to the non-emission area NEA, respectively, among the surfaces of the organic insulating layer 370 and the inorganic buffer layer 376 disposed on the touch sensor 360, and the third uneven patterns 382 are positioned on the surface of the black matrix 380. When the black matrix 380 is disposed, the external light EL reflected from the touch electrode 368 is trapped in the first and second uneven patterns 372 and 377 as well as in the third uneven pattern 382 without deteriorating process reliability and processability. In this manner, the reflection of the external light EL may be prevented, and annular spots, rainbow mura, and/or diffraction mura caused by the reflection of the external light EL may be minimized. Since a polarizing member may be obviated, the light emitting luminance of the display device 300 would not be lowered and efficient light emission may be implemented at low power.

### Third Embodiment

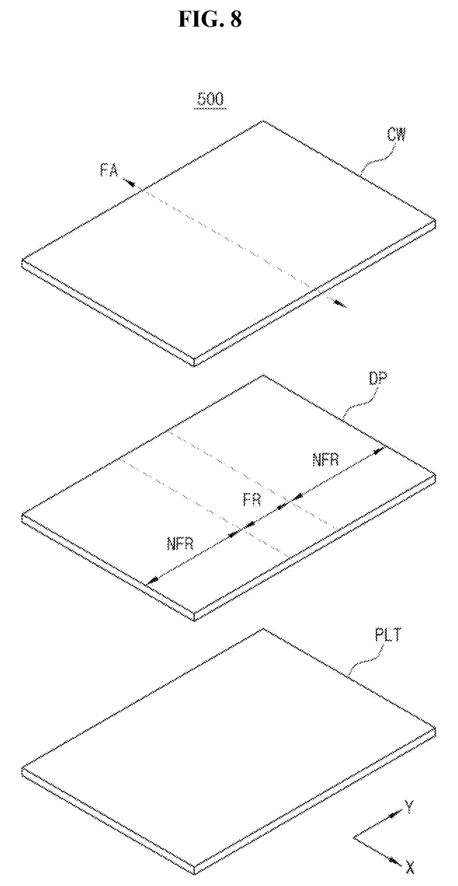

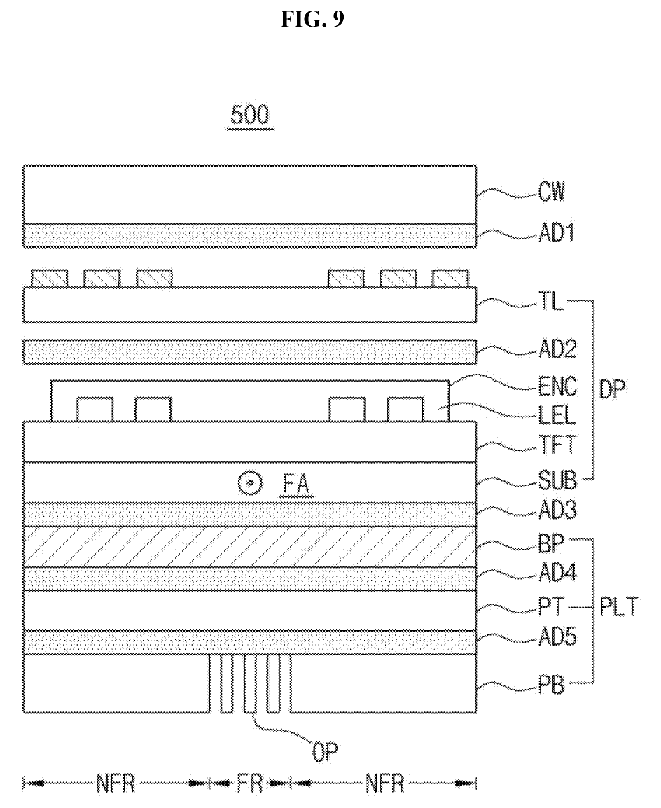

The display device in accordance with the embodiments of the present disclosure may be a foldable display device. FIG. 8 illustrates a schematic exploded perspective view of a display device in accordance with a third embodiment of the present disclosure. FIG. 9 illustrates a schematic cross-sectional view of the display device in accordance with the third embodiment of the present disclosure.

Referring to FIGS. 8 and 9, a display device 500 includes a folding region FR and a non-folding region NFR and may be folded along a first (Y) direction. The display device 500 may include the non-folding region NFR at both sides of the folding region FR along the first direction.

The display device 500 may be out-folded, in which the display surface is exposed to the outside when folded, but is not limited thereto. Alternatively, or additionally, the display device 500 may be in-folded in which the display surface is hidden therein.

In one embodiment, a display panel DP may be folded inwardly or outwardly with respect to a folding axis FA. As used herein, the folding axis FA represents a center of the folding area having a predetermined curvature due to folding by an imaginary line. While the display panel DP is described and illustrated as being foldable at a center portion in FIG. 8, the entire portion of the display panel DP may be freely deformed.

The display panel DP may include a substrate SUB including a flexible material so that the display area may be folded inwardly or outwardly, and an element layer for displaying an image. For example, the element layer may include a thin film transistor element layer TFT and a light emitting element layer LEL disposed in the display area on the substrate SUB.

An encapsulation layer ENC is disposed on the light emitting element layer LEL, a touch layer (touch sensor) TL is disposed on the encapsulation layer LED, and a cover window CW is disposed on the touch layer TL. In addition, a color filter layer and/or a black matrix may be disposed on the touch layer TL, for example, between the touch layer TL and the cover window CW.

A plate PLT is disposed on the lower surface of the substrate SUB for supporting the substrate SUB. For example, the plate PLT may include a back plate BP, a plate top PT, and a plate bottom PB disposed sequentially on the lower surface of the substrate SUB.

The thin film transistor element layer TFT includes a thin film transistor with a semiconductor layer, a gate electrode, a source electrode and a drain electrode, a gate insulating layer, and an interlayer insulating layer. The thin film transistor may have the structure illustrated in FIG. 2 or FIG. 5. The thin film transistor may be a driving thin film transistor and may include an oxide semiconductor.

The light emitting element layer LEL may include a light-emitting diode, a bank layer, an anti-reflection pattern, and/or a column spacer. The arrangements and/or shapes of the light-emitting diode, the bank layer, the anti-reflection pattern, and/or the column spacer may be substantially the same as those shown in FIGS. 2 to 7.

The substrate SUB on which the thin film transistor element layer TFT and the light emitting element layer LEL are disposed may be encapsulated by the encapsulation layer ENC. The encapsulation layer ENC prevents external oxygen and/or moisture from infiltrating to the light emitting element layer LEL.

The cover window CW constitutes an outer periphery of the display device 500. The cover window CW may be positioned outside the surface on which the image is displayed on the display panel DP, transmits the images of the display panel DP, and protects the display panel DP from external impact or stress.

The cover window CW may include a reinforced glass and/or a reinforced plastic material. For example, the cover window CW may include, but is not limited to, a material selected from high-strength reinforced glass, polyethylene terephthalate (PET), acrylic resins and/or (meth) acrylate resins such as polymethyl methacrylate (PMMA) to prevent scratches from the outside.

The back plate BP may include an organic material with beneficial folding properties. For example, the back plate BP may include, but is not limited to, a polyimide (PI).

The plate top PT and the plate bottom PB may include a metal component, and the thickness of the plate bottom PB exposed to the outside may be larger than the thickness of the plate top PT. For example, the plate top PT may include SUS301 with relatively high hardness and the plate bottom PB may include SUS313 with higher corrosion resistance and acid resistance but is not limited thereto.

The plate bottom PB includes a plurality of openings OP in the folding area FR so that the display device 500 may have improved folding property. In one embodiment, the plurality of openings OP may be configured to penetrate the surface and/or rear surface of the plate bottom PB.

A plurality of adhesive components AD1, AD2, AD3, AD4 and AD5 may be disposed between the plurality of components in the display device 500. For example, a first adhesive component AD1 may be disposed between the touch layer TL and the cover window CW, a second adhesive component AD2 may be disposed between the encapsulation layer ENC and the touch layer TL, a third adhesive component AD3 may be disposed between the substrate SUB and the back plate BP, a fourth adhesive component AD4 may be disposed between the back plate BP and the plate top PT, and a fifth adhesive component AD5 may be disposed between the plate top PT and the plate bottom PB. Each of the first to fifth adhesive components AD1, AD2, AD3, AD4, and AD5 may include an optically clear adhesive (OCA) and/or a pressure sensitive adhesive (PSA).

In accordance with the third embodiment, it is possible to minimize the stains caused by the reflection of external light, and to implement the display device with beneficial luminous efficiency. In addition, the foldable display with beneficial flexibility may be fabricated by obviating a polarizer. The display device implementing ESG can be manufactured with the advantages of low reflection and low power.

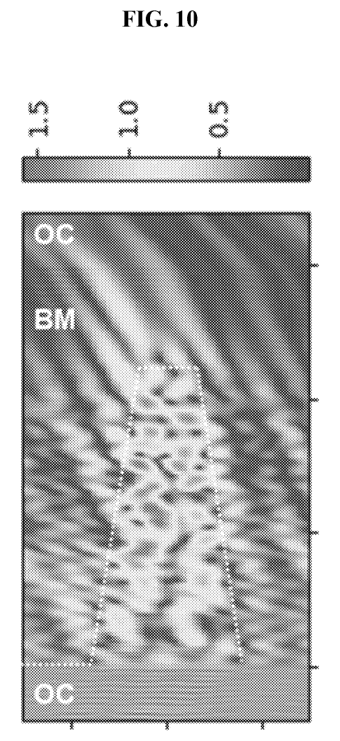

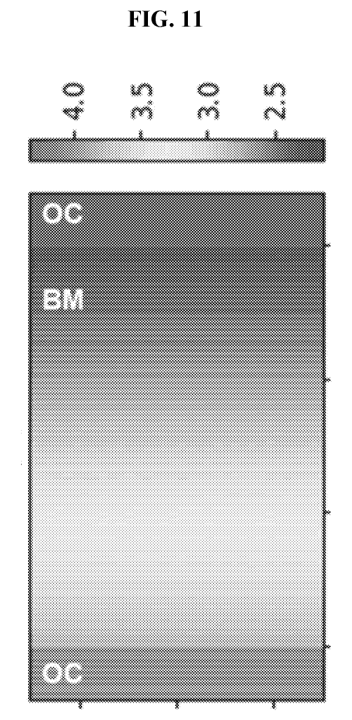

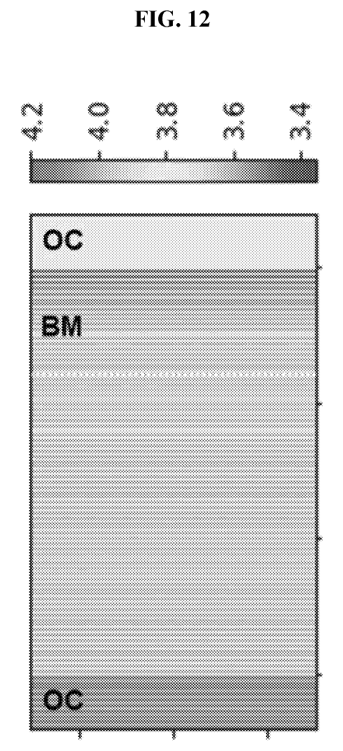

FIGS. 10 to 12 are photographs illustrating simulations of reflectance of an external light in a display device (FIG. 10) in which uneven patterns are disposed on the surfaces of an organic insulating layer and an inorganic buffer layer, a display device (FIG. 11) in which the depth of a black matrix is extended to a depth corresponding to the depth of the uneven patterns, and a display device (FIG. 12) in which the uneven patterns are not disposed on the surfaces of the organic insulating layer and the inorganic buffer layer, respectively.

Referring to FIG. 12, a simulation of external light reflectance in a display device that is not formed with the uneven patterns on the surfaces of the organic insulating layer and the inorganic buffer layer disposed on the touch electrode according to a comparative embodiment is illustrated. As compared to FIG. 12, FIG. 10 demonstrates that the external light reflectance is reduced by about 60% in the display device in which the uneven patterns are positioned on the surfaces of the organic insulating layer and the inorganic buffer layer. In addition, as compared to FIG. 12, the external light reflectance (FIG. 11) is reduced by about 50% in the display device in which the black matrix is coated to correspond to a depth of the uneven pattern.

In simulation evaluation illustrated in FIG. 10, the external light was not uniform and formed an optical path with a phase difference. When the plurality of uneven patterns, in which concave and convex portions are alternately arranged, are formed on the surface of the organic insulating layer and the inorganic buffer layer, diffraction of an external light source may be suppressed.

According to one or more embodiments, since a separate polarizer may be obviated in the display surface, the luminance of light emitted from the light-emitting diode is not reduced while the reflection of external light in the non-emission area may be greatly reduced. The display device with beneficial contrast ratio may be implemented by maximizing the luminance differences between the emission area and the non-emission area.

According to embodiments, the external light which is incident to the display device and reflected from the touch electrode is trapped in the uneven pattern and converted to un-uniform lights with phase differences. The reflection and diffraction of the external light may be suppressed.

According to embodiments, as the external light is reflected in the uneven patterns, the reflection path of the external light may be increased. The external light re-absorption in the black matrix disposed adjacently to the uneven patterns may be improved and the transmittance of the external light including long wavelength in the black matrix may be minimized.

According to embodiments, as the reflection of the external light is minimized, the stains and/or the rainbow mura caused by the light reflection from the conductive materials such as conductive films and/or electrodes in the display panel and/or caused by the refractive index differences among the films through which the light is passed through may be minimized.

According to embodiments, a polarizing member may be obviated from the display device to improve flexibility thereof, and therefore, it is possible to implement a foldable display device in which the display area is folded.

According to embodiments, the reflection of the external light may be efficiently suppressed even if the content of the light-blocking material in the black matrix is not increased. Accordingly, the reliability and processability of the black matrix may be secured.

According to embodiments, the side of the bank layer disposed adjacently to the light-emitting diode further extends to the emission area as compared to a side of the black matrix disposed adjacently to the color filter layer, thereby securing a viewing angle.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate having an emission area and a non-emission area;
a light-emitting diode disposed on the substrate in the emission area;
a touch sensor disposed on the light-emitting diode;
an organic insulating layer disposed on the touch sensor;
an inorganic buffer layer disposed on the organic insulating layer; and
a black matrix disposed on the inorganic buffer layer in the non-emission area,
wherein:
the organic insulating layer has a plurality of first uneven patterns on a surface thereof in the non-emission area; and
the inorganic buffer layer has a plurality of second uneven patterns on a surface thereof in the non-emission area.

2. The display device of claim 1, wherein the first uneven patterns include a plurality of first concave portions each of which has a wedge-shaped cross-section.

3. The display device of claim 2, wherein the first concave portions having the wedge-shaped cross-section have a height greater than a width of each of the first concave portions.

4. The display device of claim 3, wherein the height of the first concave portions is two to five times greater than the width of each of the first concave portions.

5. The display device of claim 1, wherein the first uneven patterns include a plurality of first concave portions, and a pitch between adjacent first concave portions among the first concave portions is irregular.

6. The display device of claim 1, wherein the first uneven patterns include a plurality of first concave portions and a width of each of the first concave portions is irregular.

7. The display device of claim 1, wherein:
the inorganic buffer layer has a refractive index different from a refractive index of the organic insulating layer; and
the first uneven patterns and the second uneven patterns overlap the black matrix.

8. The display device of claim 1, wherein:
the inorganic buffer layer is interposed between the organic insulating layer and the black matrix; and
a lower surface of the inorganic buffer layer in the non-emission area, on which the second uneven patterns are formed, is disposed at a lower elevation than an upper surface of the organic insulating layer in the emission area.

9. The display device of claim 1, wherein the black matrix includes a plurality of third uneven patterns on a surface thereof.

10. The display device of claim 9, wherein the third uneven patterns include a plurality of third concave portions each of which has a wedge-shaped cross-section.

11. The display device of claim 10, wherein the third concave portions having the wedge-shaped cross-section have a height greater than a width of each of the third concave portions.

12. The display device of claim 11, wherein the height of the third concave portions is two to five times greater than the width of each of the third concave portions.

13. The display device of claim 9, wherein the third uneven patterns include a plurality of third concave portions, and a pitch between adjacent third concave portions among the third concave portions is irregular.

14. The display device of claim 9, wherein the third uneven patterns include a plurality of third concave portions and a width of each of the third concave portions is irregular.

15. The display device of claim 9, wherein:
the first uneven patterns include a plurality of first concave portions, the second uneven patterns include a plurality of second concave portions, and the third uneven patterns include a plurality of third concave portions; and
at least a portion of the first concave portions and the second concave portions is positioned to be misaligned with the corresponding third concave portions.

16. The display device of claim 1, wherein the display device further comprises a bank layer disposed outside of the light-emitting diode in the non-emission area.

17. The display device of claim 16, wherein the bank layer comprises at least one of a black pigment and a black dye.

18. The display device of claim 16, wherein the display device further comprises:
a driving thin film transistor disposed on the substrate and electrically connected to the light-emitting diode;
an encapsulation layer disposed on the light-emitting diode and the bank layer; and
a color filter layer disposed on the encapsulation layer in the emission area.

19. The display device of claim 18, wherein a side of the bank layer adjacent to the light-emitting diode extends further to the light-emitting diode than a side of the black matrix.

20. The display device of claim 18, wherein the driving thin film transistor includes an oxide semiconductor.
